(19) United States
(12) Patent Application Publication
(10) Pub. No.: US 2013/0313606 A1
(43) Pub. Date: Nov. 28, 2013

(54) ILLUMINATING DEVICE

(71) Applicant: Green Crystal Energy Ltd., Zhubei City (TW)

(72) Inventors: Ming-Sheng Weng, Zhubei City (TW); Lung-Ta Hsiao, Zhubei City (TW); Che-Lu Tseng, Zhubei City (TW); Hung-Yuan Li, Zhubei City (TW)

(73) Assignee: Green Crystal Energy Ltd., Zhubei City (TW)

(21) Appl. No.: 13/897,212

(22) Filed: May 17, 2013

(30) Foreign Application Priority Data
May 22, 2012 (TW) 101118164

(51) Int. Cl. H01L 33/64

(52) U.S. Cl. CPC H01L 33/641
USPC 257/99

(57) ABSTRACT

An illuminating device includes a substrate, a circuit layer, a conductive structure, and at least one LED die. The circuit layer is disposed on a top surface of the substrate. The conductive structure is disposed on the top surface of the substrate and includes a graphite layer. The LED die is attached to the conductive structure and is electrically connected to the circuit layer through the conductive structure.

### CROSS-REFERENCE TO RELATED APPLICATION

This application claims priority of Taiwanese Application No. 101118164, filed on May 22, 2012.

### BACKGROUND OF THE INVENTION

1. Field of the Invention

This invention relates to an illuminating device, more particularly to a light emitting diode illuminating device.

2. Description of the Related Art

In recent years, light emitting diodes (abbreviated as LEDs hereinafter) have been applied in various illuminating devices due to their advantages such as long service life, high illuminating efficiency, and small volume. Among various problems encountered when incorporating the LEDs into the illuminating devices, efficiency of dissipating heat generated from the LEDs is currently one of the major issues that need to be solved in order to alleviate the shorter service life and lower illuminating efficiency of the LEDs. To solve the aforementioned problem, a conventional heat dissipating technique is to utilize a metallic heat-dissipating substrate or a ceramic heat-dissipating substrate in the die-bonding process with silver-containing adhesives. The metallic heat-dissipating substrate may be made of aluminum or copper which has high heat conductivity to dissipate heat generated from the LEDs while illuminating. Since the silver-containing adhesives have relatively low heat conductivities, another conventional method to alleviate the aforementioned problem is to utilize a eutectic bonding process with intermetallic compounds (e.g., an Au—Sn intermetallic compound) for the LEDs. However, such eutectic bonding process is complicated and results in higher costs.

### SUMMARY OF THE INVENTION

Therefore, the object of the present invention is to provide an illuminating device that may alleviate the aforesaid drawback of the prior art.

According to this invention, an illuminating device includes:

a substrate having a top surface;

a conductive structure that is disposed on the top surface of the substrate and that includes a graphite layer;

a circuit layer disposed on the top surface of the substrate; and

at least one LED die disposed on the graphite layer and electrically connected to the circuit layer.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of the first preferred embodiment of an illuminating device according to the invention;

FIG. 2 is a schematic view of the second preferred embodiment of the illuminating device according to the present invention;

FIG. 3 is a schematic view of the third preferred embodiment of the illuminating device according to the present invention; and

FIG. 4 is a schematic view of the fourth preferred embodiment of the illuminating device according to the present invention.

### DETAILED DESCRIPTION OF THE PREFERRED EMBODIMENTS

Before the present invention is described in greater detail, it should be noted that like elements are denoted by the same reference numerals throughout the disclosure.

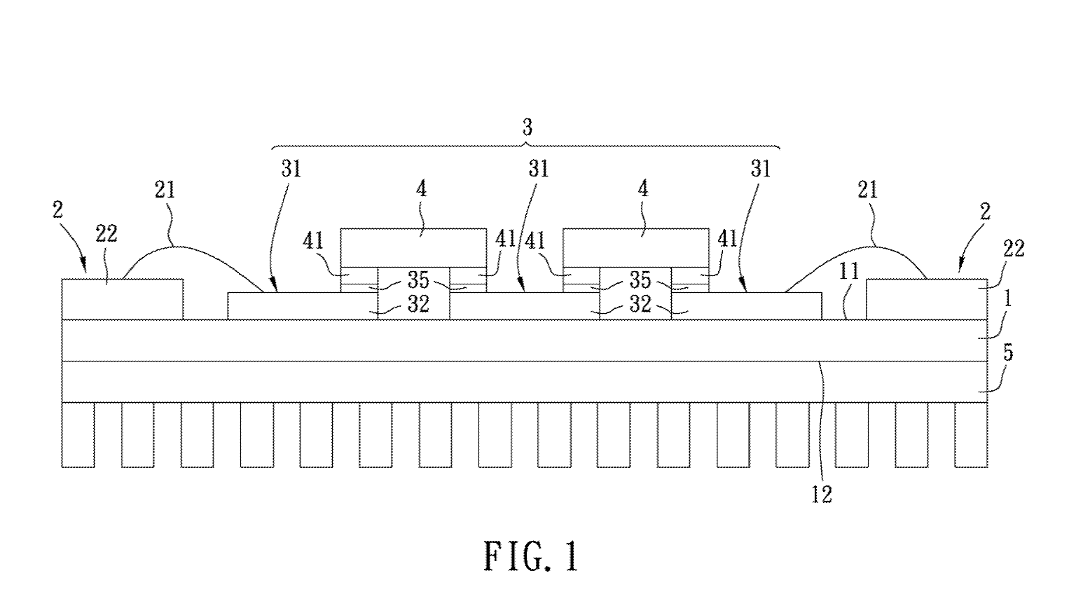

Referring to FIG. 1, the first preferred embodiment of an illuminating device according to the present invention is shown to include a substrate 1, a circuit layer 2, a conductive structure 3, two LED dies 4, and a heat sink 5.

The substrate 1 has opposite top and bottom surfaces 11 and 12 and may be one of a ceramic substrate and a metal cored printed circuit board which is an electrically insulated substrate in this embodiment.

The circuit layer 2 is disposed on the top surface 11 of the substrate 1 and includes two electrodes 22 that are spaced apart from each other. In this embodiment, the circuit layer 2 may be a printed circuit board configured in an annular shape, in two pieces or in other configurations so long as the two electrodes 22 of the circuit layer 2 are spaced apart from each other.

The conductive structure 3 is disposed on the top surface 11 of the substrate 1 and is spaced apart from the circuit layer 2. To be specific, the conductive structure 3 is disposed between the two electrodes 22 of the circuit layer 2 without physical contact with the two electrodes 22 in this embodiment. The conductive structure 3 includes a graphite layer 32 which is attached to the top surface 11 of the substrate 1 and which is divided into at least two conductive units 31. In this embodiment, the graphite layer 32 of the conductive structure 3 is divided into three spaced-apart conductive units 31. The number of the divided conductive units 31 is not limited hereto according to the present invention. The graphite layer 32 of the conductive structure 3 may be made of artificial graphite or natural graphite. Preferably, the graphite layer 32 is made of a material selected from the group consisting of graphite powder, flake graphite, and graphite foam. More preferably, the graphite layer 32 is a graphite sheet made of highly oriented pyrolytic graphite (HOPG) which is highly electrically and thermally conductive along a horizontal direction (a horizontal heat conductivity of 1500 W/mk compared to a vertical heat conductivity of 5 W/mk) so as to create a better heat distribution profile of the conductive structure 3 along the horizontal direction. Preferably, the graphite layer 32 has a thickness ranging from 5 μm to 100 μm. The graphite layer 32 can be attached to the top surface 11 of the substrate 1 via heat conductive tapes or heat conductive pastes, or through compression bonding. Each of the two electrodes 22 of the circuit layer 2 is electrically connected to an adjacent one of the three conductive units 31 by wire bonding with a wire 21. Although in this embodiment, only one wire 21 is employed for each of the two electrodes 22 to electrically connect to the corresponding one of the conductive units 31, it should be noted that the number of the wire 21 employed to electrically connect the conductive units 31 and the corresponding one of the two electrodes 22 may be different in other embodiments of the present invention.

Each of the LED dies 4 is attached to the conductive structure 3 by a flip-chip method and is electrically connected to the circuit layer 2 through a respective one of the conductive units 31 of the conductive structure 3. Generally, each of the LED dies 4 may be attached to the graphite layer 32 by a conductive adhesive 35 such as a silver-containing epoxy. In this embodiment, each of two LED dies 4 is electrically connected to an adjacent pair of the conductive units 31. That is, each of the LED dies 4 has a P electrode 41 electrically connected to one in an adjacent pair of the three conductive units 32 and an N electrode 41 electrically connected to the other one in the adjacent pair of the three conductive units 32. Consequently, the two LED 4 dies and the electrodes 22 of the circuit layer 2 are electrically connected through the three conductive units 32, so as to electrically connect the two LED dies 4 in series. However, it should be noted that the two LED dies 4 may be electrically connected in parallel. Moreover, the numbers of the LED die 4 and the conductive units 32 are not limited hereto. For example, in series connection, when the number of the LED dies 4 is 3, the number of the conductive units 32 should be at least 4.

The heat sink 5 is attached to the bottom surface 12 of the substrate 1 for dissipating heat from the substrate 1.

When power is supplied to the circuit layer 2 and to the LED dies 4 through the wires 21 and the conductive units 32, the LED dies 4 are driven to illuminate light. In the meantime, while illuminating, the generated heat of the LED dies 4 may be conducted by the at least two conductive units 31 due to the superior heat conductivity of graphite along the horizontal direction, so as to create a better heat distribution profile of the illuminating device and to alleviate the overheating problem of the LED dies 4 for maintaining the illuminating efficiency thereof.

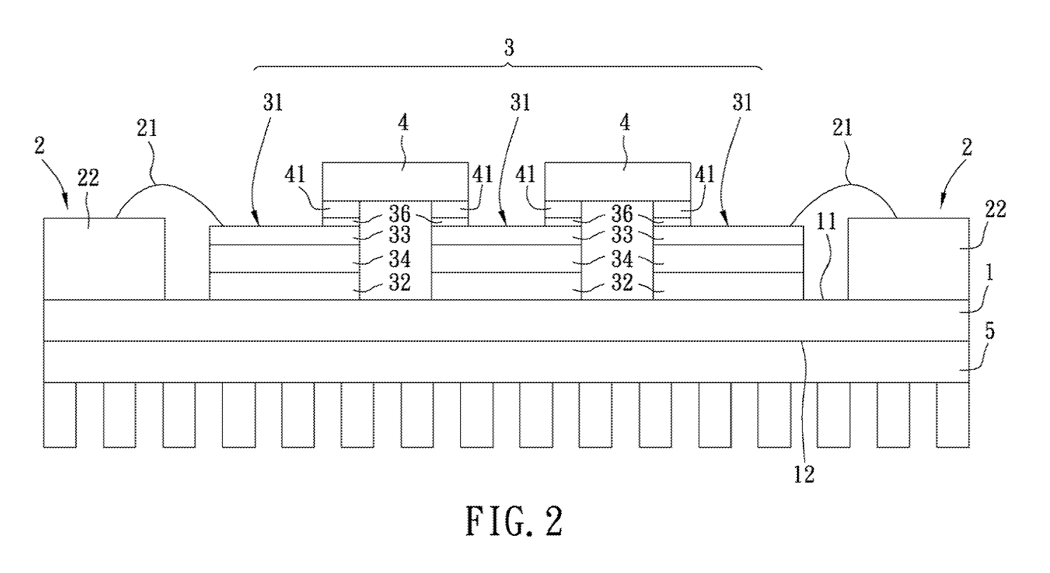

Referring to FIG. 2, the second preferred embodiment of the illuminating device according to the present invention is shown to be similar to the first preferred embodiment. The difference between the first and second preferred embodiments resides in the configuration of the conductive structure 3. In the second preferred embodiment, the conductive structure 3 includes a graphite layer 32 that is disposed on the top surface 11 of the substrate 1, a heat conductive layer 34, and an electrically conductive layer 33 that is disposed on and electrically insulated from the heat conductive layer 34. In this embodiment, the electrically conductive layer 33 is divided to form three separated conductive units 31, and each of the graphite layer 32 and the heat conductive layer 34 is divided into a plurality of spaced-apart regions each of which corresponds to a respective one of the conductive units 31. The LED dies 4 are attached on the electrically conductive layer 33 of the conductive structure 3 by metal balls 36 via a ball bonding process, so as to electrically connect the LED dies 4 and the electrically conductive layer 33. Preferably, the metal balls 36 may be solder balls or Au—Sn alloy balls. Preferably, the heat conductive layer 34 is a silicon interposer, and the electrically conductive layer 33 is made of gold.

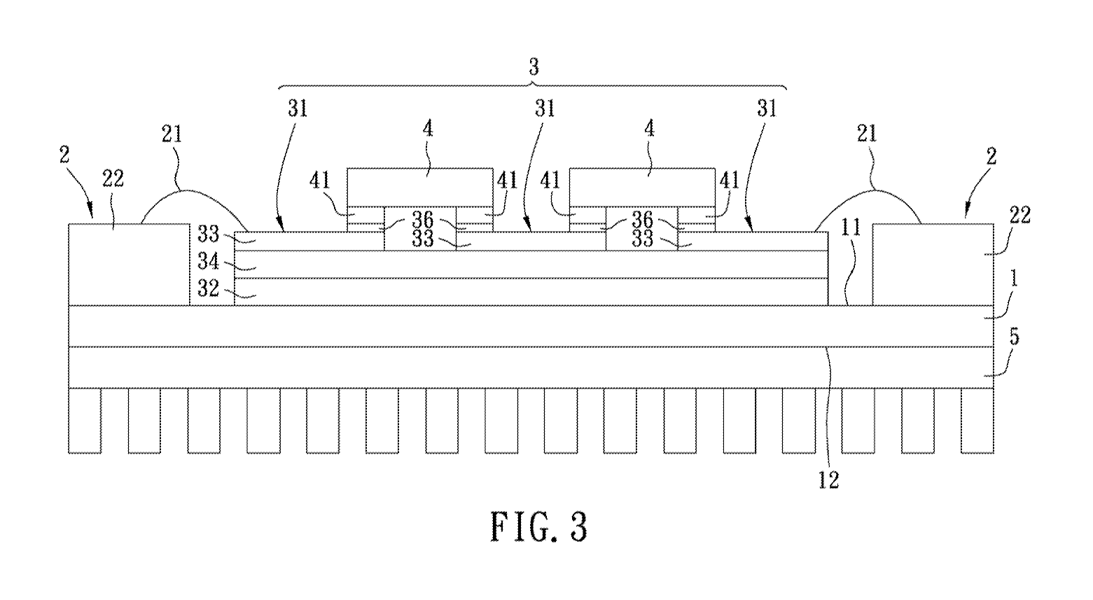

Referring to FIG. 3, the third preferred embodiment of the illuminating device according to the present invention is shown to be similar to the second preferred embodiment. The difference between the second and third preferred embodiments resides in the configuration of the conductive structure 3 as well. That is, in this preferred embodiment, the graphite layer 32 and the heat conductive layer 34 are configured in a plate shape, rather than being divided into a plurality of spaced-apart regions. Compared to the second preferred embodiment, such configuration of the graphite layer 32 allows a better utilization of the superior heat conductivity of graphite along the horizontal direction, so as to achieve a better heat distribution profile of the conductive structure 3.

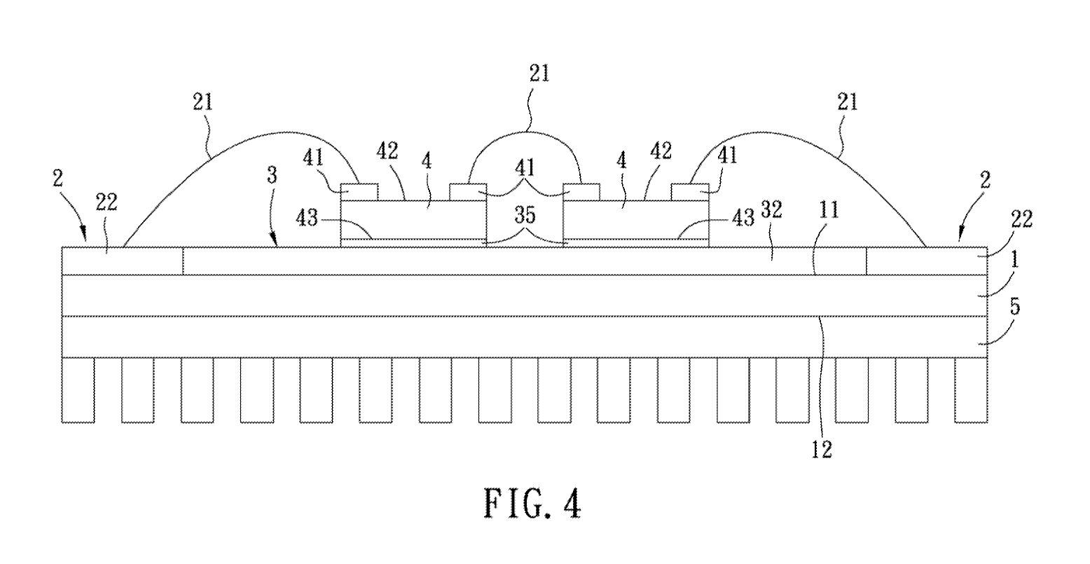

Referring to FIG. 4, the fourth preferred embodiment of the illuminating device of the present invention is shown to be similar to the first preferred embodiment. The difference between the first and fourth preferred embodiments resides in that the graphite layer 32 of the conductive structure 3 merely has a heat conducting function. That is, each of the LED dies 4 has opposite top and bottom surfaces 42, 43 and two electrodes 41 that are formed on the top surface 42. Electrical connection between the two LED dies 4 and electrical connection between the LED dies 4 and the circuit layer 2 are achieved by wire bonding with a plurality of wires 21 via the electrodes 41 of the LEDs 4, instead of using a flip-chip method in conjunction with the graphite layer 32. In this embodiment, since the conductive structure 3 only has the heat conducting function, the LED dies 4 can be attached to the graphite layer 32 by an adhesive 35 that is not necessarily to be electrically conductive.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An illuminating device comprising:
a substrate having a top surface;
a conductive structure disposed on said top surface of said substrate and including a graphite layer;
a circuit layer disposed on said top surface of said substrate; and
at least one LED die attached on said conductive structure and electrically connected to said circuit layer.

2. The illuminating device as claimed in claim 1, wherein said conductive structure is divided into at least two conductive units which are spaced apart from each other, said at least one LED die being attached to said conductive units of said conductive structure by a flip-chip method and being electrically connected to said circuit layer through said conductive units.

3. The illuminating device as claimed in claim 2, wherein said substrate is an electrically insulated substrate, said graphite layer being disposed on said top surface of said substrate and being divided to form said conductive units, said at least one LED die being attached to said graphite layer by a conductive adhesive.

4. The illuminating device as claimed in claim 2, wherein said graphite layer is disposed on said top surface of said substrate, said conductive structure further including a heat conductive layer that is disposed on said graphite layer, and an electrically conductive layer that is disposed on said heat conductive layer and that is divided to form said conductive units of said conductive structure.

5. The illuminating device as claimed in claim 4, wherein each of said graphite layer and said heat conductive layer is divided into a plurality of spaced-apart regions each of which corresponds to a respective one of said conductive units.

6. The illuminative device as claimed in claim 4, wherein both of said graphite layer and said heat conductive layer are configured in a plate shape.

7. The illuminating device as claimed in claim 4, wherein said at least one LED die is attached on said electrically conductive layer by metal ball bonding.

8. The illuminating device as claim 4, wherein said electrically conductive layer is made of gold.

9. The illuminating device as claim 4, wherein said heat conductive layer is a silicon interposer.

10. The illuminating device as claimed in claim 3, wherein said conductive adhesive is a silver containing epoxy.

11. The illuminating device as claimed in claim 1, wherein said at least one LED die is electrically connected to said circuit layer by wire bonding.

12. The illuminating device as claimed in claim 1, wherein said graphite layer is made of one of natural graphite and artificial graphite.

13. The illuminating device as claimed in claim 1, wherein said graphite layer is made of a material that is selected from the group consisting of graphite powder, flake graphite, expanded graphite, and graphite foam.

14. The illuminating device as claimed in claim 1, wherein said graphite layer is made of highly oriented pyrolytic graphite.

15. The illuminating device as claimed in claim 14, wherein said graphite layer has a thickness ranging from 5 μm to 100 μm.

16. The illuminating device as claimed in claim 1, wherein said substrate is one of a ceramic substrate and a metal core printed circuit board.

17. The illuminating device as claimed in claim 1, wherein said substrate further has a bottom surface, said illuminating device further comprising a heat sink attached on said bottom surface of said substrate.

18. The illuminating device as claimed in claim 1, wherein said circuit layer is a circuit board.
